(19) United States
(12) Patent Application Publication
(10) Pub. No.: US 2019/0237441 A1
(43) Pub. Date: Aug. 1, 2019

(54) DISPLAY DEVICE, DISPLAY SYSTEM, AND MANUFACTURING METHOD OF DISPLAY DEVICE

(71) Applicant: SHARP KABUSHIKI KAISHA, Osaka (JP)

(72) Inventor: HIROYOSHI HIGASHISAKA, Sakai City (JP)

(21) Appl. No.: 16/237,129

(22) Filed: Dec. 31, 2018

(30) Foreign Application Priority Data
Jan. 29, 2018 (JP) 2018-012573

(51) Int. Cl. H01L 25/075; H01L 23/544; H01L 33/56; H01L 33/50; H01L 21/66; H01L 33/00

(52) U.S. Cl. CPC H01L 25/0753; H01L 23/544; H01L 33/56; H01L 33/502; H01L 2933/0041; H01L 33/0079; H01L 2223/54406; H01L 2933/005; H01L 22/12

(57) ABSTRACT

A display device includes plural pixel elements that are arranged on a foundation substrate in a matrix manner. Among the plural pixel elements, outside pixel elements positioned in an outer periphery are set as a non-display region, and inside pixel elements positioned on an inside are set as a display region.

### BACKGROUND

### 1. Field

The present disclosure relates to a display device including plural pixel elements that are arranged on a foundation substrate in a matrix manner, a display system, and a manufacturing method of the display device.

### 2. Description of the Related Art

In related art, a display device has been known in which plural pixel elements are arranged on a substrate in a matrix manner. For such a display device, it has been suggested to provide dummy elements around a display region (for example, see Japanese Unexamined Patent Application Publication No. 2007-93685, Japanese Unexamined Patent Application Publication No. 2001-195026, and Japanese Patent No. 4576647).

An electro-optical device disclosed in Japanese Unexamined Patent Application Publication No. 2007-93685 is configured to have display pixels that belong to an effective display region which performs image display and dummy pixels that belong to a peripheral region and has a configuration in which dummy elements do not operate, differently from the display pixels. Accordingly, power consumption by the dummy elements is saved.

A matrix-type display device disclosed in Japanese Unexamined Patent Application Publication No. 2001-195026 includes light emitting elements that configure a display panel and contribute to display and dummy elements that configure the display panel but do not contribute to display. In this configuration, electrical characteristics of the dummy elements are measured, and the results are reflected on control of voltage or current of the light emitting elements.

A dot-matrix display device disclosed in Japanese Patent No. 4576647 is configured to include display elements bonded to crossing positions between scanning lines and signal lines, dummy display elements (dummy elements) bonded to the scanning lines, a first voltage source that supplies an output voltage to the display elements, and a second voltage source that supplies a lower voltage than the output voltage and has a configuration in which charges accumulated in the display elements are discharged via the dummy display elements. In this configuration, incorrect display by the display elements is avoided by performing a discharge operation.

In the above-described configuration, the dummy element supplements an electrical role. However, the role is limited and lacks flexibility for various situations.

It is desirable to provide a display device, a display system, and a manufacturing method of a display device, which improve a yield by setting an optimal display region for arrangement of pixel elements on a substrate.

### SUMMARY

A display device according to the present disclosure is a display device including: plural pixel elements that are arranged on a substrate in a matrix manner. Among the plural pixel elements, outside pixel elements that are positioned in an outer periphery are set as a non-display region and inside pixel elements that are positioned on an inside of the outside pixel elements are set as a display region.

A display system according to the present disclosure includes the display device according to the present disclosure.

A manufacturing method of a display device according to the present disclosure is a manufacturing method of a display device including plural pixel elements that are arranged on a substrate in a matrix manner, the manufacturing method including: forming the plural pixel elements on a same growth substrate; and joining the pixel elements formed on the growth substrate to a foundation substrate. Among the plural pixel elements, outside pixel elements that are positioned in an outer periphery are set as a non-display region and inside pixel elements that are positioned on an inside of the outside pixel elements are set as a display region.

### BRIEF DESCRIPTION OF THE DRAWINGS

FIG. 1 is a schematic cross-sectional diagram of a display device according to a first embodiment of the present disclosure;

FIG. 2 is a schematic top diagram of the display device illustrated in FIG. 1;

FIG. 3 is a schematic explanatory diagram that illustrates a manufacturing method (growing step) of the display device;

FIG. 4 is a schematic explanatory diagram that illustrates the manufacturing method (separating step) of the display device;

FIG. 5 is a schematic plan diagram of FIG. 4;

FIG. 6 is a schematic explanatory diagram that illustrates the manufacturing method (joining step) of the display device;

FIG. 7 is a schematic explanatory diagram that illustrates the manufacturing method (filling step) of the display device;

FIG. 8 is a schematic explanatory diagram that illustrates the manufacturing method (peeling step) of the display device;

FIG. 9 is a schematic explanatory diagram that illustrates the manufacturing method (polishing step) of the display device;

FIG. 10 is an explanatory diagram that illustrates behavior of light radiated from pixel elements in a comparative example;

FIG. 11 is an explanatory diagram that illustrates behavior of light radiated from the pixel elements in the display device according to the first embodiment of the present disclosure;

FIG. 12 is a schematic top diagram that illustrates an outline of a display device according to a second embodiment of the present disclosure; and

FIG. 13 is a schematic cross-sectional diagram of a display device according to a third embodiment of the present disclosure.

### DESCRIPTION OF THE EMBODIMENTS

### First Embodiment

A display device according to a first embodiment of the present disclosure will hereinafter be described with reference to drawings.

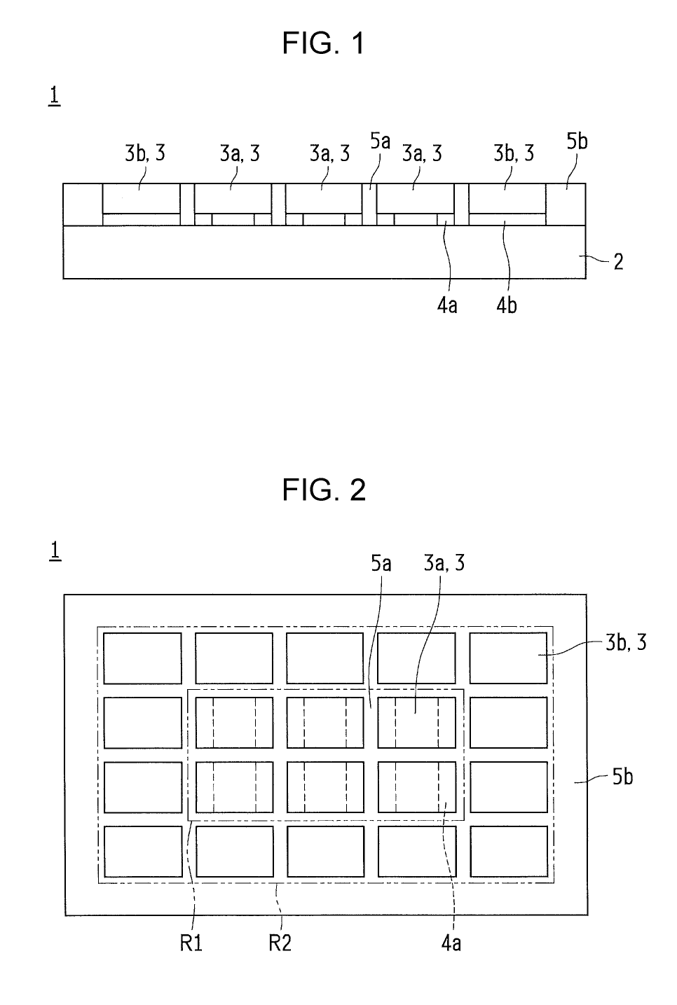

FIG. 1 is a schematic cross-sectional diagram of the display device according to the first embodiment of the present disclosure. FIG. 2 is a schematic top diagram of the display device illustrated in FIG. 1. Note that FIG. 1 is not hatched in consideration of ease of viewing of the drawing.

In a display device 1 according to the first embodiment of the present disclosure, plural pixel elements 3 are arranged on a foundation substrate 2 in a matrix manner. As illustrated in FIG. 2, among the plural pixel elements 3, outside pixel elements 3b positioned in an outer periphery are set as a non-display region R2, and inside pixel elements 3a positioned on an inside are set as a display region R1. FIG. 2 illustrates an example where rectangular-shaped pixel elements 3 are arranged in four rows×five columns. In each row and each column, the pixel elements arranged at the head and tail correspond to the outside pixel elements 3b. Note that in order to illustrate the positional relationship between the inside pixel elements 3a and the outside pixel elements 3b, FIG. 1 illustrates the pixel elements 3 that correspond to the second row and the third row in FIG. 2. Further, in FIG. 2, the pixel elements 3 are arranged in four rows×five columns. However, embodiments are not limited to this, but the number of pixel elements to be arranged on the foundation substrate 2 may appropriately be set.

The pixel element 3 is joined to the foundation substrate 2 via an electrode. In the following, the electrodes may be distinguished by referring to the electrode that corresponds to the inside pixel element 3a as inside electrode 4a and by referring to the electrode that corresponds to the outside pixel element 3b as outside electrode 4b.

Portions among the pixel elements 3 are filled with resin. In the following, the resin may be distinguished by referring to the resin that corresponds to the display region R1 as inside resin 5a and by referring to the resin that corresponds to the non-display region R2 and an outer periphery of the foundation substrate 2 as outside resin 5b. That is, in a top view, the inside pixel elements 3a are surrounded by the inside resin 5a, and the outside pixel elements 3b are surrounded by the outside resin 5b.

Next, details of portions will be described together with a manufacturing method of the display device 1 with reference to the drawings.

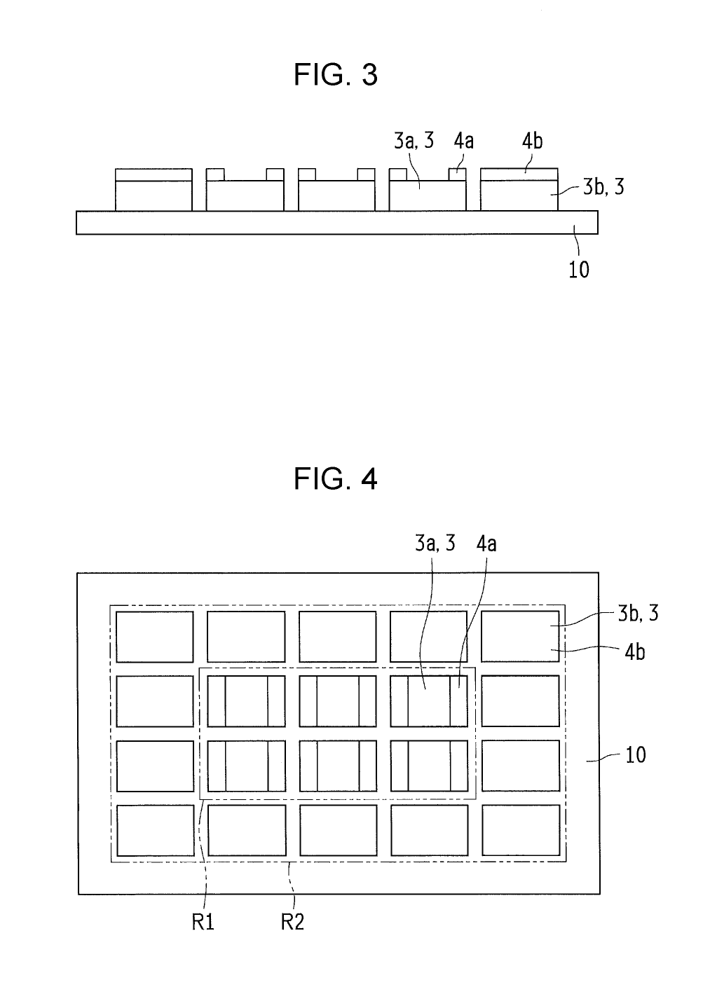

FIG. 3 is a schematic explanatory diagram that illustrates the manufacturing method (growing step) of the display device.

As for the pixel element 3, a semiconductor light emitting element in related art may be used, and an LED may be used. As structures of a semiconductor layer 11 of the pixel element 3, a homostructure, a heterostructure, and a double-heterostructure, which have a p-n junction, are raised. FIG. 3 illustrates a growth substrate 10 on which the semiconductor layer 11 is laminated. The semiconductor layer 11 is formed on the growth substrate 10 by epitaxial growth. In this embodiment, the growth substrate 10 is formed of sapphire. However, the growth substrate 10 is not limited to this but may be any material that enables epitaxial growth of the semiconductor layer 11.

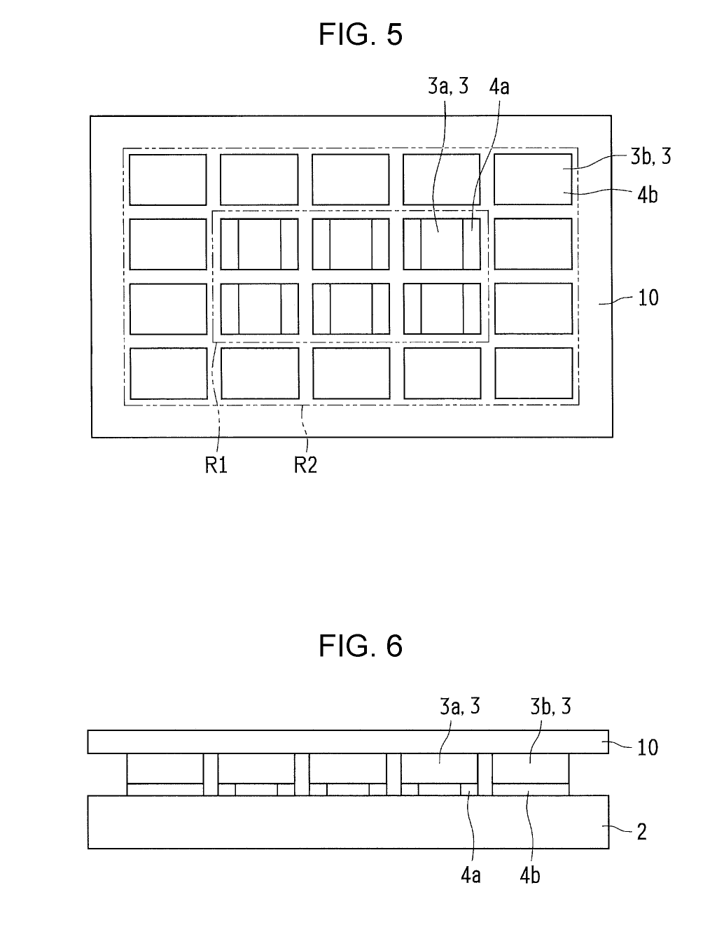

FIG. 4 is a schematic explanatory diagram that illustrates the manufacturing method (separating step) of the display device. FIG. 5 is a schematic plan diagram of FIG. 4.

After the growing step illustrated in FIG. 3, formation of electrodes and separation of elements are performed. Specifically, on the semiconductor layer 11, the inside electrode 4a and the outside electrode 4b are formed corresponding to the positions of the inside pixel element 3a and the outside pixel element 3b. The electrodes are formed by an electrode formation technique in related art, and metal such as Au is used, for example. Note that the electrodes are not limited to those, but use of an alloy or lamination of plural materials is possible.

In addition, the semiconductor layer 11 is etched by a selective etching process such that the growth substrate 10 is partially exposed. Accordingly, the semiconductor layer 11 as one body is divided (separated) into plural pixel elements 3.

FIG. 6 is a schematic explanatory diagram that illustrates the manufacturing method (joining step) of the display device.

After the separating step illustrated in FIG. 4, the pixel element 3 is joined to the foundation substrate 2. Specifically, the surface of the growth substrate 10 on which the pixel elements 3 are provided is opposed to the foundation substrate 2, and the foundation substrate 2 and the growth substrate 10 are pressed to each other. Note that although not illustrated in FIG. 6, wiring may in advance be formed with electrodes or the like on the foundation substrate 2 or may be patterned in response to the positions of the inside pixel elements 3a and the outside pixel elements 3b.

The material for the foundation substrate 2 is not particularly limited. For example, a material may be used in which a driving circuit which controls light emission by the pixel elements 3 is formed on Si.

In the pixel elements on the growth substrate 10, it is desirable that the area of the outside electrode 4b is more largely configured than the area of the inside electrode 4a. Accordingly, the joint strength with the foundation substrate 2 may be reinforced by the outside pixel elements 3b. In other words, strong joint by the outside pixel elements 3b provided in the outer periphery may support the joint by the inside pixel elements 3a.

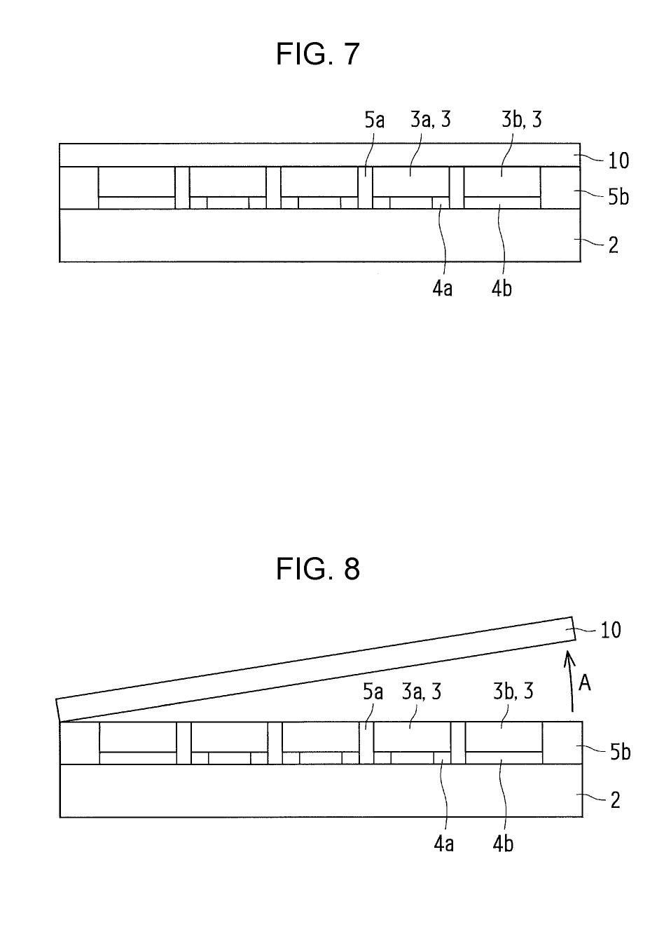

FIG. 7 is a schematic explanatory diagram that illustrates the manufacturing method (filling step) of the display device.

After the joining step illustrated in FIG. 6, the portions among the pixel elements 3 are filled with the resin. The resin is liquid resin such as silicone-based resin or epoxy-based resin, which is injected by a microneedle or the like that matches the size of a gap, and is thereafter cured. A method for curing the liquid resin is not particularly limited, but irradiation with ultra-violet light or heating is possible.

In a case of filling a gap or the like with the resin, if a very open space is present, supply to such a portion is promoted, supply to another portion is delayed, and unevenness of the filling amount of the resin occurs. In this embodiment, when the portions among the separated pixel elements 3 are filled with the resin, the manners in which the inside pixel elements 3a are surrounded are the same between the outer periphery and a central portion because the outside pixel elements 3b are provided. Thus, filling with the resin may be performed uniformly.

FIG. 8 is a schematic explanatory diagram that illustrates the manufacturing method (peeling step) of the display device.

After the filling step illustrated in FIG. 7, the growth substrate 10 is peeled from the pixel elements 3. When the growth substrate 10 is peeled, a force is added in the direction in which one end of the growth substrate 10 is parted from the foundation substrate 2 (the direction of a reference character A in FIG. 8). The force added to the growth substrate 10 is likely to be added to the pixel elements 3 that are positioned in the outermost periphery among the pixel elements 3. Here, because the pixel elements 3 positioned in the outermost periphery are the outside pixel elements 3b, an influence on the inside pixel elements 3a may be reduced, and a yield of the pixel elements 3 may be improved.

Further, in a top view, the area that is occupied by the resin in the display region R1 is desirably 30% or less. That is, the area of the resin that does not contribute to display is reduced to a small area as much as possible, and reinforcement by the outside pixel elements 3b and the resin may thereby be realized while a requested image quality is secured. In addition, the area occupied by the resin is reduced to a small area, the area in which the resin contacts with the growth substrate 10 is thereby made small, and peeling of the growth substrate 10 is thereby facilitated.

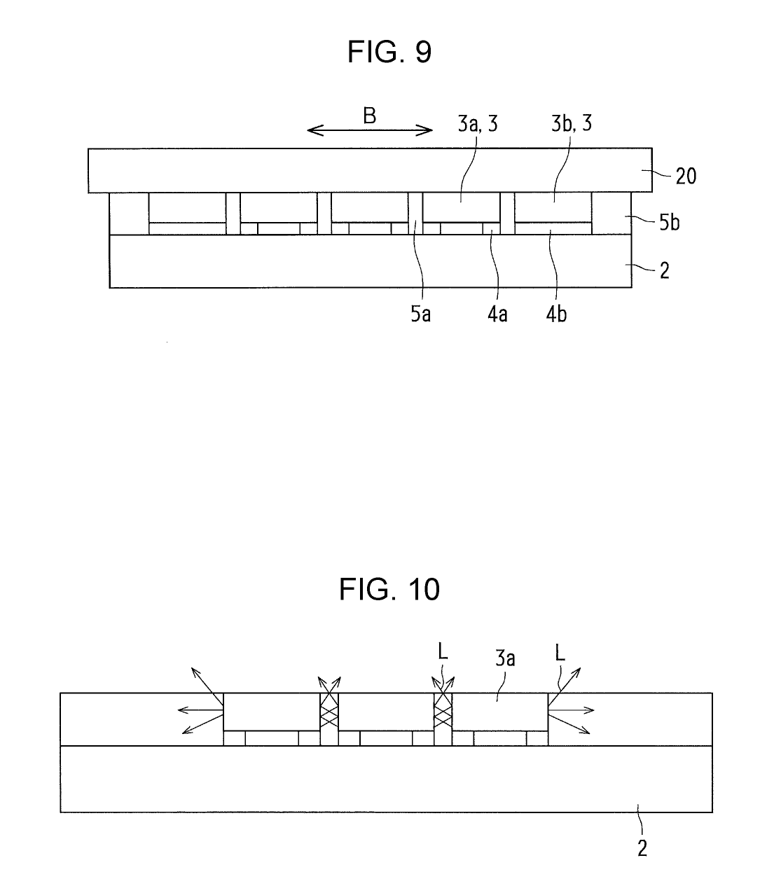

FIG. 9 is a schematic explanatory diagram that illustrates the manufacturing method (polishing step) of the display device.

After the peeling step illustrated in FIG. 8, surfaces (upper surfaces) of the pixel elements 3 are polished. Polishing of the pixel elements 3 may be conducted by CMP or the like, for example. Specifically, in the polishing step, in a state where upper surface sides of the pixel elements 3 in the display device 1 are pressed to a polishing plate 20, the display device 1 and/or the polishing plate 20 are slid in the direction along the upper surfaces of the pixel elements 3 (the direction of a reference character B in FIG. 9). In this case, a load is likely to be applied to the pixel elements 3 positioned in the outermost periphery, and the scraped amount becomes large. Here, the outside pixel elements 3b are provided such that the inside pixel elements 3a are not included in the positions where non-uniform polishing is likely to occur, an influence on the display region R1 may thereby be reduced, and non-uniformity of a light emitting surface may be decreased.

The display device 1 illustrated in FIG. 1 is manufactured through the above-described steps. A characteristic evaluating step may be performed for the display device 1 that is manufactured in the above manner. The evaluating step is conducted by causing the outside pixel elements 3b to emit light. In other words, the outside pixel elements 3b that are simultaneously formed with the inside pixel elements 3a in the growing step are caused to emit light, and electrical characteristics or a finishing quality as the light emitting element may thereby be evaluated. Further, the outside pixel elements 3b are actually caused to emit light, and the joint state or the like between the electrodes and the pixel elements 3 may thereby be recognized. In such a manner, the characteristics of the outside pixel element 3b are evaluated, and the characteristics of the inside pixel element 3a may thereby be estimated.

Next, the relationship between the light radiated from the pixel element 3 and the neighboring pixel element 3 will be described with reference to the drawings.

FIG. 10 is an explanatory diagram that illustrates behavior of light radiated from pixel elements in a comparative example.

In order to describe the behavior of light, a case of the comparative example will first be described. The comparative example has a configuration in which the outside pixel elements 3b are not provided, differently from the display device 1 illustrated in FIG. 1. Specifically, FIG. 10 illustrates a state where three inside pixel elements 3a are arranged side by side, and a periphery of the display region R1 is not surrounded by the non-display region R2. The pixel element 3 is configured to radiate light mostly from the upper surface. However, a portion of light (side surface light L) is radiated also from a side surface. The resin here does not completely block the side surface light L but transmits a portion thereof. Note that FIG. 10 does not illustrate the light radiated from the upper surfaces of the pixel elements 3 in consideration of ease of viewing of the drawing.

The side surface light L is reflected by the neighboring pixel element 3 or the like and is emitted from an upper surface side of the display device 1. However, the pixel elements 3 provided in the outermost periphery have surfaces that do not have neighboring pixel elements 3, and the side surface light L is radiated so as to spread laterally from those surfaces. As a result, a difference in the way of emission of the side surface light L occurs between the outermost periphery and the inside and becomes a cause of non-uniformity of the light emitting surface.

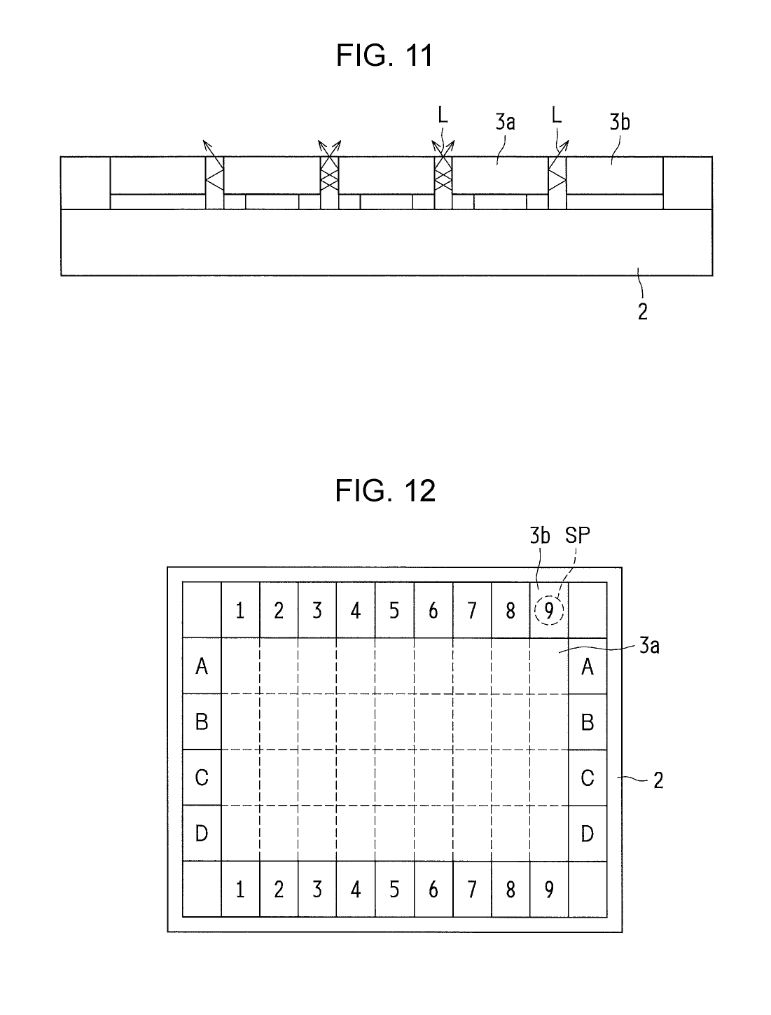

FIG. 11 is an explanatory diagram that illustrates behavior of light radiated from the pixel elements in the display device according to the first embodiment of the present disclosure.

FIG. 11 illustrates the behavior of the side surface light L in the above-described display device 1 illustrated in FIG. 1. As described above, in the display device 1 according to the first embodiment of the present disclosure, the pixel elements 3 (outside pixel elements 3b) positioned in the outermost periphery are set as the non-display region R2 and are controlled such that they do not emit light. In other words, even a periphery of the inside pixel elements 3a positioned in an outer periphery in the display region R1 is surrounded by the outside pixel elements 3b of the non-display region R2. Thus, the side surface light L radiated from the inside pixel elements 3a positioned in the outer periphery in the display region R1 is reflected by the outside pixel elements 3b and is emitted from the upper surface side of the display device 1 similarly to the other portions. In such a manner, the environments in which the inside pixel elements 3a are arranged (the way of being surrounded) become the same between the outer periphery and the inside, crosstalk of light may be made uniform, and non-uniformity of the light emitting surface due to light radiated to the periphery may be remedied.

### Second Embodiment

A display device according to a second embodiment of the present disclosure will next be described with reference to the drawings. Note that the same reference characters are provided to configuration elements that have similar functions to the first embodiment, and descriptions thereof will not be made.

FIG. 12 is a schematic top diagram that illustrates an outline of the display device according to the second embodiment of the present disclosure.

The second embodiment is different from the first embodiment in that an identification pattern SP is provided to the electrode of the outside pixel element 3b. Specifically, the identification pattern SP indicates the matrix of the pixel element 3 and is set as a shape that depicts a character or a figure, for example. The identification pattern SP may be set as a shape that is viewable by a user, a machine, or the like when the display device 1 is seen from the upper surface side and may be provided with a different numeral or character in the orders of row and column. For example, in a case where a numeral is used as the identification pattern SP, the value may sequentially be increased from “1”. Further, in a case where a character is used, the character may be provided in the alphabetical order. In such a manner, the identification pattern SP provided along the outer periphery of the display region R1 is checked, the position of the pixel element 3 in the display region R1 may thereby be recognized easily, and work efficiency in a failure analysis or the like may be improved. Further, a character or figure is used as the identification pattern SP, and the matrix of the pixel elements 3 may visually be recognized.

The identification pattern SP may be formed with an electrode or the like and be in a shape of a character or numeral itself or may be only a border as a punched shape, for example. Note that the identification pattern SP is not limited to the above-described configuration but may be a combination of plural characters or figures. In other words, plural characters may be provided to one outside pixel element 3b. Further, a two-dimensional barcode, in which plural rectangles are regularly aligned, or the like may be used as the identification pattern SP.

### Third Embodiment

A display device according to a third embodiment of the present disclosure will next be described with reference to the drawings. Note that the same reference characters are provided to configuration elements that have similar functions to the first and second embodiments, and descriptions thereof will not be made.

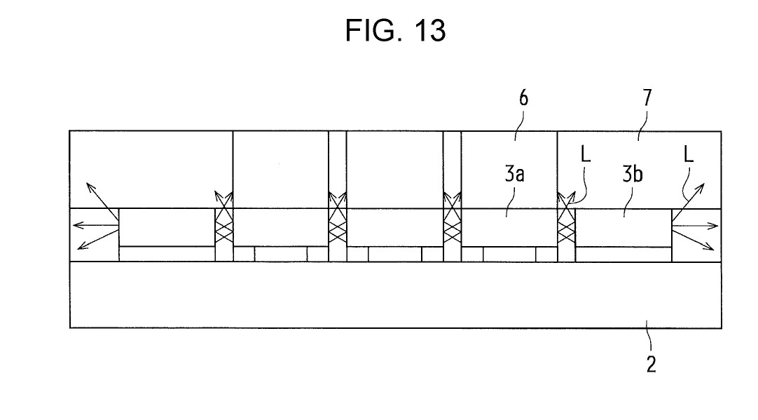

FIG. 13 is a schematic cross-sectional diagram of the display device according to the third embodiment of the present disclosure.

The third embodiment is different from the first embodiment in that a phosphor layer 6 (color conversion layer) that covers an upper surface of the inside pixel element 3a is included. Specifically, the phosphor layer 6 is provided corresponding to each of the inside pixel elements 3a, and the outside pixel elements 3b and gaps between the pixel elements 3 are covered by light shielding resin 7.

The phosphor layer 6 is formed of a phosphor material, a color conversion material, a light scattering material, resin to be a base material, and so forth and acts on the light radiated from the inside pixel element 3a. The phosphor layer 6 converts the wavelength of the light radiated from the inside pixel element 3a and emits light in a color such as red, green, blue, or yellow. Note that the phosphor layer 6 is not limited to this but may be formed as a transparent layer. Further, not all the phosphor layers 6 have to have the same configuration with respect to plural inside pixel elements 3a, but the phosphor layers 6 may be configured to convert light into respectively different colors.

In the above-described first embodiment and second embodiment, a description is made about a case where the outside pixel elements 3b are not lit when the inside pixel elements 3a are lit. However, in the third embodiment, the outside pixel elements 3b may be lit when the inside pixel elements 3a are lit. For example, when all the pixel elements 3 in the display region R1 are lit (in a fully lit state), it is desirable to light the outside pixel elements 3b that neighbor the inside pixel elements 3a in the outermost periphery in order to cause the inside pixel elements 3a in the outermost periphery and on the inside to have similar appearance. As illustrated in FIG. 13, because the side surface light L radiated from the neighboring pixel elements 3 is also incident on the phosphor layers 6, how the colors look may be made uniform by lighting the outside pixel elements 3b. However, because display may become different in a case where the outside pixel elements 3b themselves are actively seen, the outside pixel elements 3b are covered by the light shielding resin 7. Note that it goes without saying that instead of the light shielding resin 7, a light shielding frame may make the outside pixel element 3b invisible from the outside. Further, except in the fully lit state, the outside pixel elements 3b do not have to emit light as long as the outside pixel elements 3b are simply present.

In the above-described embodiments, descriptions are made about the foundation substrate 2. However, it goes without saying that the foundation substrate 2 is not limited to the above-described embodiments but may be a substrate of a semiconductor chip such as an LSI chip other than common substrates such as glass epoxy substrates, for example. Incidentally, an LSI chip on a pixel element represents a stack structure.

Note that the embodiments disclosed herein are exemplary in all aspects, and do not serve as a basis for limited interpretation.

Further, although not particularly limited, the display device 1 according to the present disclosure may properly be used for display systems such as liquid crystal displays, virtual reality (VR) systems, augmented reality (AR) systems, mixed reality (MR) systems, laser projection devices, and LED projection devices.

Consequently, the technical scope of the present disclosure is not interpreted only with the above embodiments but is defined based on the scope of the claims. Further, the technical scope of the present disclosure includes all modifications within meanings equivalent to the scope of the claims and the scope thereof.

The present disclosure contains subject matter related to that disclosed in Japanese Priority Patent Application JP 2018-012573 filed in the Japan Patent Office on Jan. 29, 2018, the entire contents of which are hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A display device comprising:
plural pixel elements that are arranged on a substrate in a matrix manner,
wherein among the plural pixel elements, outside pixel elements that are positioned in an outer periphery are set as a non-display region and inside pixel elements that are positioned on an inside of the outside pixel elements are set as a display region.

2. The display device according to claim 1,
wherein the outside pixel element is provided with an identification pattern that indicates a matrix of the inside pixel element.

3. The display device according to claim 2,
wherein the identification pattern is set as a shape that depicts a character or a figure.

4. The display device according to claim 1,
wherein the plural pixel elements are separated from one another, and
wherein portions among the plural pixel elements are filled with resin.

5. The display device according to claim 4,
wherein in a top view, an area that is occupied by the resin in the display region is set to 30% or less.

6. The display device according to claim 1, further comprising:
a phosphor layer that covers the inside pixel element.

7. A display system comprising:
the display device according to claim 1.

8. A manufacturing method of a display device including plural pixel elements that are arranged on a substrate in a matrix manner, the manufacturing method comprising:
forming the plural pixel elements on a same growth substrate; and
joining the pixel elements formed on the growth substrate to a foundation substrate,
wherein among the plural pixel elements, outside pixel elements that are positioned in an outer periphery are set as a non-display region and inside pixel elements that are positioned on an inside of the outside pixel elements are set as a display region.

9. The manufacturing method of a display device according to claim 8, further comprising:
separating the plural pixel elements from one another; and
filling portions among the plural pixel elements with resin.

10. The manufacturing method of a display device according to claim 8, further comprising:
peeling the plural pixel elements from the growth substrate.

11. The manufacturing method of a display device according to claim 10, further comprising:
polishing surfaces of the plural pixel elements that are peeled from the growth substrate.

12. The manufacturing method of a display device according to claim 8,
wherein in the pixel elements, an area of an electrode of the outside pixel element is more largely configured than an area of an electrode of the inside pixel element.

13. The manufacturing method of a display device according to claim 8, further comprising:
evaluating the outside pixel element, the outside pixel element being set as a light emitting element, by causing the outside pixel element to emit light.
